(19) United States
(12) Patent Application Publication
(10) Pub. No.: US 2022/0021185 A1
(43) Pub. Date: Jan. 20, 2022

(54) OPTOELECTRONIC SEMICONDUCTOR COMPONENT HAVING A CURRENT DISTRIBUTION LAYER AND METHOD FOR PRODUCING THE OPTOELECTRONIC SEMICONDUCTOR COMPONENT

(71) Applicant: OSRAM Opto Semiconductors GmbH, Regensburg (DE)

(72) Inventors: Martin BEHRINGER, Regensburg (DE); Alexander BEHRES, Pfatter (DE); Matin MOHAJERANI, Regensburg (DE)

(21) Appl. No.: 17/297,688

(22) PCT Filed: Nov. 29, 2019
(86) PCT No.: PCT/EP2019/083046

§ 371 Date: May 27, 2021

(30) Foreign Application Priority Data
Nov. 30, 2018 (DE) 10 2018 130 562.1

(51) Int. Cl. H01S 5/183; H01S 5/327; H01S 5/042

(52) U.S. Cl. CPC H01S 5/18361; H01S 5/0421; H01S 5/18388; H01S 5/327

(57) ABSTRACT

An optoelectronic semiconductor component has a first semiconductor layer of a p-conductivity type, a second semiconductor layer of an n-conductivity type and also an n-doped current distribution layer containing ZnSe and adjoining the second semiconductor layer.

### CROSS-REFERENCE TO RELATED APPLICATIONS

This patent application is a national stage entry of International Patent Application No. PCT/EP2019/083046, filed on Nov. 29, 2019, and published as WO 2020/109530 A1 on Jun. 4, 2020, and claims the benefit of priority of German patent application DE 10 2018 130 562.1, filed Nov. 30, 2018, the disclosure contents of all of which are incorporated herein by reference.

### BACKGROUND

Surface-emitting lasers, i.e. laser devices, in which the generated laser light is emitted perpendicular to a surface of a semiconductor layer assembly, are used as laser light sources in numerous applications.

The object of the present invention is to provide an improved optoelectronic semiconductor component. Another object of the present invention is to provide an improved method for the production of an optoelectronic semiconductor component.

According to embodiments, the object is achieved by the subject matter and the method of the independent claims. Advantageous enhancements are defined in the dependent claims.

### SUMMARY

An optoelectronic semiconductor component comprises a first semiconductor layer of a p-conductivity type, a second semiconductor layer of an n-conductivity type and an n-doped current spreading layer which contains ZnSe and is adjacent to the second semiconductor layer.

According to embodiments, the optoelectronic semiconductor component further comprises a first and a second resonator mirror. For example, the first semiconductor layer is part of the first resonator mirror, and the second semiconductor layer is part of the second resonator mirror.

According to further embodiments, the second resonator mirror may be embodied as a dielectric Bragg mirror, which is arranged on a side of the n-doped current spreading layer facing away from the second semiconductor layer. As an example, the dielectric Bragg mirror may be directly adjacent to the n-doped current spreading layer. According to further embodiments, an intermediate layer may also be arranged between the n-doped current spreading layer and the dielectric Bragg mirror.

The optoelectronic semiconductor component may furthermore comprise a transparent substrate which is arranged on a side of the n-doped current spreading layer facing away from the second semiconductor layer. As an example, the transparent substrate may be patterned to form a lens.

According to embodiments, the optoelectronic semiconductor component may be a surface-emitting semiconductor laser component.

A method for producing an optoelectronic semiconductor component comprises forming a first semiconductor layer of a p-conductivity type, forming a second semiconductor layer of an n-conductivity type, and forming an n-doped current spreading layer which contains ZnSe and is adjacent to the second semiconductor layer.

The first semiconductor layer may, for example, be formed as part of a first resonator mirror, and the second semiconductor layer is formed as part of a second resonator mirror.

According to embodiments, the first semiconductor layer and the second semiconductor layer may be formed over a growth substrate, thereby obtaining a workpiece. As an example, a growth substrate composed of suitably doped or undoped GaAs or ZnSe may be used.

The first semiconductor layer is, for example, formed prior to forming the second semiconductor layer. The method may further include rebonding the workpiece onto a transparent substrate, so that the transparent substrate is arranged on a side of the current spreading layer facing away from the second semiconductor layer.

According to further embodiments, the second semiconductor layer may be formed prior to forming the first semiconductor layer. The method may further include, for example, rebonding the workpiece onto a working substrate prior to forming the current spreading layer, so that the first semiconductor layer is arranged on the side of the working substrate.

The method may furthermore include rebonding the workpiece onto a transparent substrate after forming the current spreading layer, so that the transparent substrate is arranged on a side of the current spreading layer facing away from the second semiconductor layer.

The method may further include patterning the transparent substrate into a lens.

According to further embodiments, the current spreading layer is formed prior to forming the second semiconductor layer and prior to forming the first semiconductor layer, thereby obtaining a workpiece.

The method may further include rebonding the workpiece onto a working substrate so that a surface of the current spreading layer is exposed.

According to embodiments, the method may further include forming a dielectric Bragg mirror over the current spreading layer.

An optoelectronic device contains the optoelectronic semiconductor component described above. As an example, the optoelectronic device is an iris scanner.

### BRIEF DESCRIPTION OF THE DRAWINGS

The accompanying drawings serve to provide an understanding of exemplary embodiments of the invention. The drawings illustrate exemplary embodiments and, together with the description, serve for explanation thereof. Further exemplary embodiments and many of the intended advantages will become apparent directly from the following detailed description. The elements and structures shown in the drawings are not necessarily shown to scale relative to each other. Like reference numerals refer to like or corresponding elements and structures.

FIG. 1A shows a schematic cross-sectional view of an optoelectronic semiconductor component according to embodiments.

FIG. 1B shows a cross-sectional view of an optoelectronic semiconductor component according to further embodiments.

FIG. 1C shows a cross-sectional view of an optoelectronic semiconductor component according to further embodiments.

FIGS. 2A and 2B show cross-sectional views of a workpiece to illustrate steps of a method for producing an optoelectronic semiconductor component.

FIGS. 3A and 3B show cross-sectional views of a workpiece to illustrate steps of a method for producing an optoelectronic semiconductor component according to further embodiments.

FIGS. 4A to 4C show cross-sectional views of a workpiece to illustrate steps of a method for producing an optoelectronic semiconductor component in accordance with further embodiments.

FIG. 5 shows an electronic device according to embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since there are also other exemplary embodiments, and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material or of an insulating material, for example sapphire. Depending on the intended use, the semiconductor may be based on a direct or an indirect semiconductor material. Examples of semiconductor materials particularly suitable for generating electromagnetic radiation include, without limitation, nitride semiconductor compounds, by means of which, for example, ultraviolet, blue or longer-wave light may be generated, such as GaN, InGaN, AlN, AlGaN, AlGaInN, phosphide semiconductor compounds by means of which, for example, green or longer-wave light may be generated, such as GaAsP, AlGaInP, GaP, AlGaP, and other semiconductor materials such as AlGaAs, SiC, ZnSe, GaAs, ZnO, Ga₂O₃, diamond, hexagonal BN and combinations of the materials mentioned. The stoichiometric ratio of the ternary compounds may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may, for example, be in a plane perpendicular to a direction of growth when layers are grown.

The term “vertical” as used in this description is intended to describe an orientation which is essentially perpendicular to the first surface of the semiconductor substrate or semiconductor body. The vertical direction may correspond, for example, to a direction of growth when layers are grown.

To the extent used herein, the terms “have”, “include”, “comprise”, and the like are open-ended terms that indicate the presence of said elements or features, but do not exclude the presence of further elements or features. The indefinite articles and the definite articles include both the plural and the singular, unless the context clearly indicates otherwise.

In the context of this description, the term “electrically connected” means a low-ohmic electrical connection between the connected elements. The electrically connected elements need not necessarily be directly connected to one another. Further elements may be arranged between electrically connected elements.

The term “electrically connected” also encompasses tunnel contacts between the connected elements.

As will be explained as part of the present description, the optoelectronic semiconductor component according to embodiments comprises an optical resonator which is formed between a first and a second resonator mirror. The first and the second resonator mirrors may each be designed as a DBR layer stack (“distributed bragg reflector”) and may comprise a multiplicity of alternating thin layers of different refractive indices. The thin layers may each be composed of a semiconductor material or alternatively of a dielectric material. As an example, the layers may alternately have a high refractive index (n>3.1 when using semiconductor materials, n>1.7 when using dielectric materials) and a low refractive index (n<3.1 when using semiconductor materials, n<1.7 when using dielectric materials). As an example, the layer thickness may be λ/4 or a multiple of λ/4, wherein λ is the wavelength of the light to be reflected in the corresponding medium. The first or the second resonator mirror may comprise 2 to 50 individual layers, for example. A typical layer thickness of the individual layers may be about 30 to 150 nm, for example 50 nm. The layer stack may furthermore include one or two or more layers of a thickness greater than approximately 180 nm, for example greater than 200 nm.

In the following, embodiments are described with reference to a semiconductor laser component. Other embodiments may relate to other optoelectronic semiconductor components such as light emitting diodes (“LEDs”) or optoelectronic detectors.

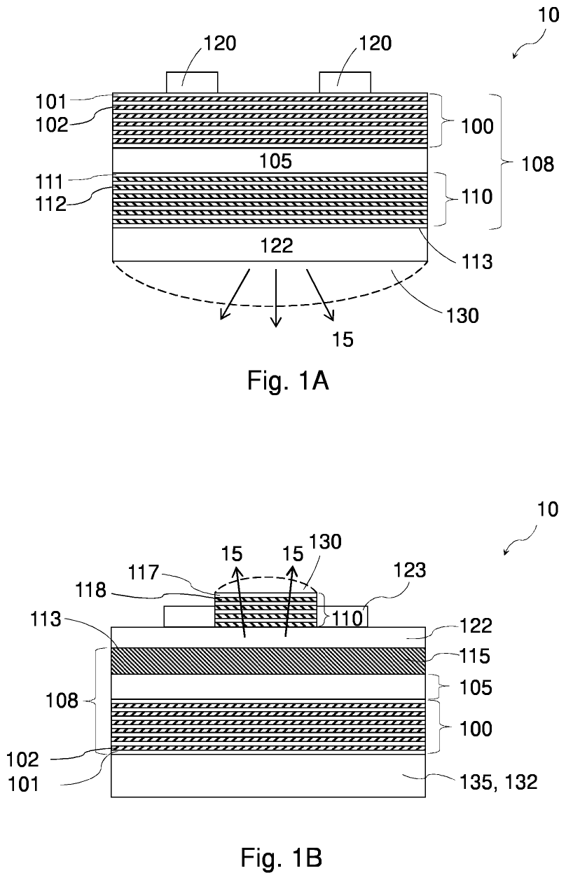

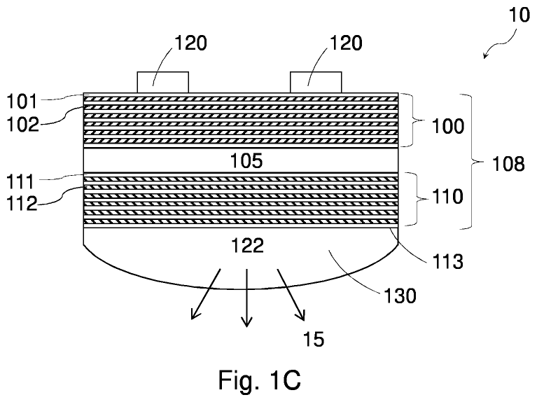

FIG. 1A shows a vertical cross-sectional view of a semiconductor laser component 10 according to embodiments. The semiconductor laser component 10 shown in FIG. 1A is suitable for emitting electromagnetic radiation 15 in a direction perpendicular to a first main surface 113 of a semiconductor body 108. The semiconductor laser component 10 comprises a first semiconductor layer 101, 102 of a p-conductivity type and a second semiconductor layer 111, 112 of an n-conductivity type. The semiconductor laser component 10 further comprises an n-doped current spreading layer 122. The n-doped current spreading layer 122 contains ZnSe and is adjacent to the second semiconductor layer 111, 112. For example, the semiconductor body 108 may include a first resonator mirror 100, a second resonator mirror 110 and an active zone 105 arranged between the first and the second resonator mirrors 100, 110. The first semiconductor layer 101, 102 may in each case be part of the first resonator mirror 100. According to embodiments, the second semiconductor layer 111, 112 may be part of the second resonator mirror 110.

The first resonator mirror 100 may, for example, comprise alternately stacked first layers 101 of a first composition and second layers 102 of a second composition. The second resonator mirror 110 may also comprise alternately stacked layers 111, 112, each having a different composition. The alternately stacked layers of the first or the second resonator mirror 100, 110 each have different refractive indices as explained above. As an example, the first resonator mirror 100 may have a total reflectivity of 99.8% or more for the laser radiation. The second resonator mirror 110 may be designed as a coupling-out mirror for the radiation from the resonator and comprises a lower reflectivity than the first resonator mirror 100, for example.

An active zone 105 may, for example, be arranged between the first and the second resonator mirror 100, 110. The active zone 105 may, for example, comprise a pn junction, a double heterostructure, a single quantum well structure (SQW, single quantum well) or a multiple quantum well structure (MQW, multi quantum well) for generating radiation. The term “quantum well structure” does not imply any particular meaning here with regard to the dimensionality of the quantization. Therefore it includes, among other things, quantum wells, quantum wires and quantum dots as well as any combination of these layers.

Electromagnetic radiation 15 generated in the active zone 105 may be reflected between the first resonator mirror 100 and the second resonator mirror 110 in such a way that a radiation field for the generation of coherent radiation (laser radiation) is formed in the resonator via induced emission in the active zone. Overall, the layer thickness of the active zone corresponds to at least the effective emitted wavelength (λ/n, wherein n corresponds to the refractive index of the active zone), so that standing waves may form inside the resonator. The generated laser radiation 15 may be coupled out of the resonator via the second resonator mirror 110, for example. The semiconductor laser component thus forms a so-called VCSEL, i.e. a semiconductor laser comprising a vertical resonator (“vertical-cavity surface-emitting laser”).

According to embodiments, the alternately stacked layers for forming the first and/or second resonator mirror 100, 110 may comprise semiconductor layers, of which at least one layer is doped. According to embodiments shown in FIG. 1, at least one semiconductor layer of the stacked layers of the first resonator mirror 100 may be doped with dopants of the p-conductivity type. Furthermore, at least one of the semiconductor layers of the second resonator mirror 110 may be doped with dopants of the n-conductivity type.

The semiconductor layers of the first and the second resonator mirrors 100, 110 and the active zone 105 may, for example, be based on the AlGaAs layer system and may each include layers of the AlₓGa_{y}In_{1-x-y}As composition, with 0<x, y<1. According to further embodiments, the semiconductor layers of the first and second resonator mirrors 100, 110 and of the active zone 105 may also be based on the InGaAlP material system and may comprise semiconductor layers of the InₓGa_{y}Al_{1-x-y}P_{z}As_{1-z} composition with 0<x, y, z<1.

The semiconductor laser component 10 furthermore comprises a first electrical contact element 120. The semiconductor laser component 10 further comprises an n-doped current spreading layer 122. The n-doped current spreading layer may contain ZnSe or a ZnSe compound. For example, the current spreading layer 122 may contain ZnSe with an admixture of sulfur. An admixture of sulfur may, for example, amount to about 4 to 8%, for example 6%. A layer thickness of the current spreading layer 122 may be 10 μm to 100 μm, for example. With 6% of sulfur admixed, ZnSe has the same lattice constant as gallium arsenide. According to embodiments, the ZnSe-containing current spreading layer may be single-crystalline.

In comparison with, for example, conductive oxides, a ZnSe-based current spreading layer has a higher conductivity. It is furthermore translucent to a greater degree. For example, it may have higher transparency in a wavelength range from approximately 800 to 900 nm, which is, for example, emitted by the semiconductor laser component. Further, a ZnSe-based layer may be doped very well with dopants of the n-conductivity type, so that a good electrical connection may be effected between the current spreading layer and the semiconductor layer. According to embodiments, the ZnSe-based current spreading layer may be formed over the entire surface area. According to further embodiments, it may be patterned appropriately.

Furthermore, according to embodiments, the layers of the first resonator mirror 100 are connected to the first electrical contact element 120. As an example, the layers of the first resonator mirror 100 may be controlled via the first electrical contact element 120. In addition, the layers of the second resonator mirror 110 may be controlled via the current spreading layer 122. By applying a suitable voltage between the first contact element 120 and the current spreading layer 122, the semiconductor laser component 10 is electrically pumpable.

According to embodiments, the semiconductor laser component may comprise further elements that are known in the field of surface-emitting lasers, for example an oxide aperture.

According to further embodiments, the semiconductor laser component 10 may furthermore comprise a lens 130, as shown in FIG. 1A. For example, the lens may be composed of an insulating material that is transparent to the emitted electromagnetic radiation. As an example, glass, Al₂O₃ or AlN may be used as the material for the lens 130. According to further embodiments, the lens may also be omitted. The lens 130 may, for example, be produced by patterning a transparent substrate and may include a transparent substrate material. When using a lens, the beam angle of the semiconductor laser component may be adjusted. According to further embodiments, instead of or in addition to the lens 130, further optical elements may be combined. The lens 130 or the corresponding optical element may be arranged in direct contact with the current spreading layer 122.

FIG. 1B shows a cross-sectional view of a semiconductor laser component 10 in accordance with further embodiments. Unlike the semiconductor laser component shown in FIG. 1A, the second resonator mirror 110 is in this case composed of dielectric layers 117, 118. As an example, the second semiconductor layer 115 of the n-conductivity type may be arranged between the active zone 105 and the n-doped current spreading layer 122. The second resonator mirror 110, which in this case is designed as a dielectric resonator mirror, is arranged on a side of the current spreading layer 122 facing away from the second semiconductor layer 115. Additionally, the semiconductor laser component may comprise second contact elements 122 for electrically contacting with the current spreading layer 122. The semiconductor laser component 10 may furthermore have a suitable substrate 132, 135, for example made of silicon. According to embodiments, the substrate may correspond to the growth substrate 132 for the semiconductor laser device 10. According to further embodiments, the substrate may be different from the growth substrate. For example, the substrate may be a working substrate 135. For example, a lens 130 may be arranged above the second resonator mirror 110. The lens may be composed, for example, of a dielectric material that is part of the first or the second dielectric layer 117, 118 of the second resonator mirror 110.

According to further embodiments, the current spreading layer 122 itself may also be patterned to form an optical element 130, for example. The ZnSe-based current spreading layer 122 may, for example, be patterned to form a converging lens. This embodiment is shown in FIG. 1C.

Furthermore, the embodiments shown in FIG. 1B may be further modified by patterning the current spreading layer 122 between the active zone 105 and the second dielectric resonator mirror 110 to form an optical element. The current spreading layer 122 may, for example, be patterned to form a converging lens. In this case, the dielectric sub-layers 117, 118 for building up the second resonator mirror 110 may be curved.

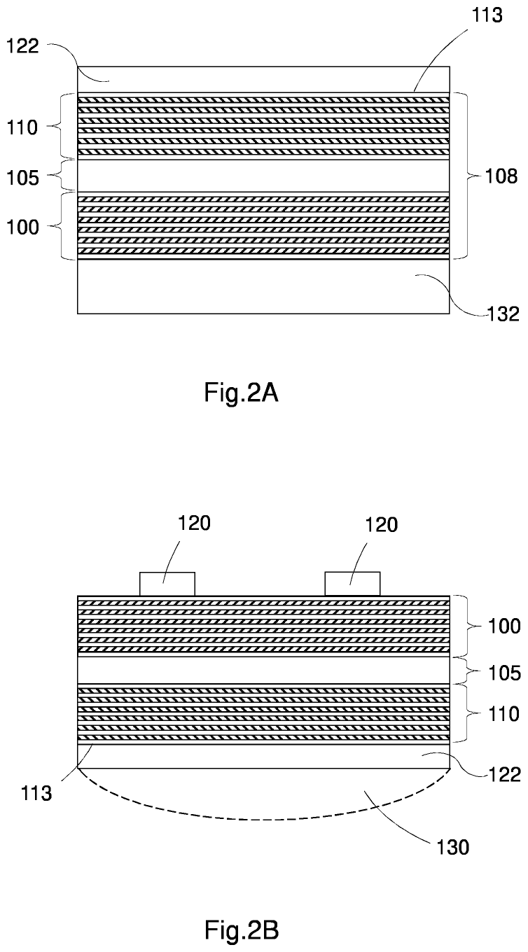

FIGS. 2A and 2B each show cross-sectional views of a workpiece to illustrate a method for producing a semiconductor laser component according to embodiments. First, a semiconductor body 108 is formed over a suitable growth substrate 132, for example by epitaxial growth. The growth substrate may be p- or undoped gallium arsenide. As an example, a first resonator mirror 100 is first grown by growing a multiplicity of first and second layers as explained above. For example, at least one of the layers of the first resonator mirror may be p-doped. Then the active zone 105 is formed, followed by the individual layers of the second resonator mirror. According to embodiments shown in FIGS. 2A and 2B, the second resonator mirror 110 is composed of semiconductor layers, at least one of which is n-doped. As an example, first and second resonator mirrors and the active zone 105 may be based on the AlGalnAs or the InGaAlPAs material system, as has been explained above.

An n-doped current spreading layer 122 containing ZnSe is then formed over the first main surface 113 of the semiconductor body 108. The ZnSe-containing current spreading layer 122 may be applied, for example, using MBE (“molecular beam epixtaxy”) or MOVPE (“metal-organic vapor phase epitaxy”, organometallic epitaxy process from the gas phase). FIG. 2A shows a cross-sectional view of an example of a resulting workpiece.

Then, as illustrated in FIG. 2B, the workpiece shown in FIG. 2A is rebounded onto a transparent substrate, for example a sapphire substrate. After the growth substrate 132 has been removed from the semiconductor body 108, first contact elements 120 are formed adjacent to the first resonator mirror 100. Furthermore, the transparent substrate may be patterned to form a lens 130. FIG. 2B shows an example of a resulting semiconductor laser component. The semiconductor laser component shown in FIG. 2B corresponds to the one shown in FIG. 1A.

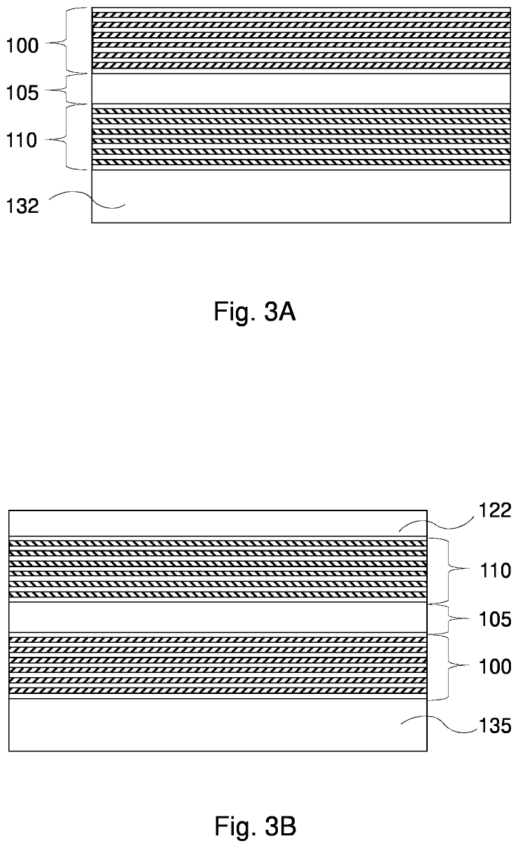

FIGS. 3A and 3B illustrate a method according to further embodiments. Again, the starting point is a growth substrate 132, which may, for example, be a GaAs substrate or a ZnSe substrate. The growth substrate 132 may be undoped or n-doped. Then a semiconductor body 108 is again applied. This time, the second resonator mirror 110 is applied first, then the active zone 105 and then the first resonator mirror 100. The second resonator mirror 110 comprises at least one n-doped semiconductor layer. The first resonator mirror 100 comprises at least one p-doped semiconductor layer. FIG. 3A shows a cross-sectional view of an example of a resulting workpiece.

Then the workpiece shown in FIG. 3A is rebonded onto a working substrate 135, which may be a silicon substrate 135, for example. As a result, the first resonator mirror 100 is adjacent to the working substrate 135, while a surface of the second resonator mirror 110 is exposed. The current spreading layer 122, which contains ZnSe and is n-doped, is then formed over the second resonator mirror 110. Subsequently, a rebonding onto a sapphire substrate may take place, so that the semiconductor laser component shown in FIG. 2B may be created as a result.

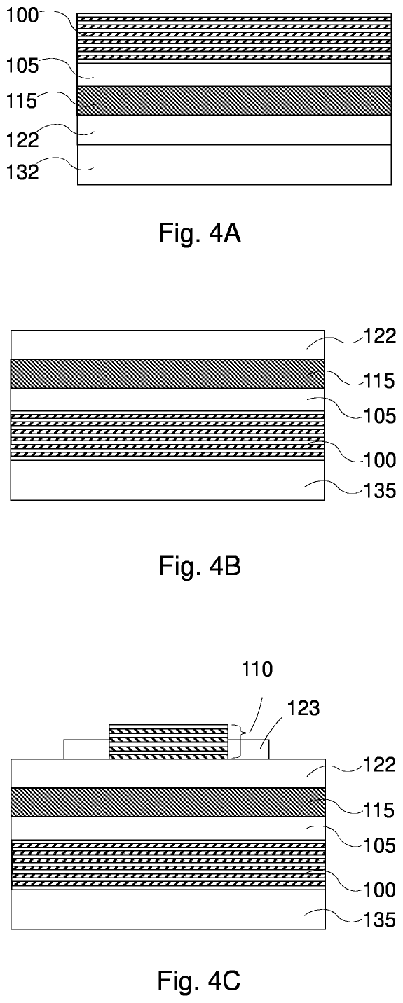

FIG. 4A to 4C show cross-sectional views of a workpiece to illustrate a method for producing the semiconductor laser component 10 illustrated in FIG. 1B. First, the ZnSe-containing current spreading layer 122 is formed over a suitable growth substrate 132. For example, the growth substrate 132 may be a GaAs substrate so that the current spreading layer 122 may be epitaxially grown. The current spreading layer 122 is n-doped. An n-doped semiconductor layer 115, for example made of GaAs, is then grown epitaxially over the n-doped current spreading layer. Subsequently, the active zone 105 and the first resonator mirror 100 are formed. As a result, the workpiece shown in FIG. 4A, for example, is obtained.

The workpiece is then rebonded onto a working substrate 135. The working substrate 135 may be a silicon substrate, for example. According to further embodiments, the working substrate 135 may also be composed of another suitable material. As a result, the layers of the first resonator mirror 100 are adjacent to the working substrate 135, and a surface of the current spreading layer 122 is exposed. FIG. 4B shows a cross-sectional view of an example of a resulting workpiece.

The second resonator mirror 110 is then formed over the current spreading layer 122. The second resonator mirror 110 may, for example, be formed to have a smaller surface area than the lateral extension of the semiconductor body 108. This results in an optical confinement of the electromagnetic radiation generated. As an example, second contact elements 123 may be formed adjacent to the second resonator mirror 110. FIG. 4C shows a cross-sectional view of a resulting semiconductor laser component. This corresponds to the semiconductor laser component shown in FIG. 1B.

As has been described, the fact that the current spreading layer which is adjacent to the second semiconductor layer contains ZnSe may provide a very highly conductive and transparent current spreading layer. As the ZnSe layer may be doped, it may comprise particularly high conductivity. Furthermore, it may be formed to be single-crystalline, for example by epitaxial growth. Accordingly, it comprises high conductivity. Due to its high conductivity, the current spreading layer is suitable for supplying power to the semiconductor chip in the case of large chip sizes. The current spreading layer described may be easily integrated into the optoelectronic semiconductor component. As a result, the optoelectronic semiconductor component may, for example, be combined with a transparent insulating substrate. As an example, this transparent insulating substrate may be patterned to form a lens. Accordingly, the optoelectronic semiconductor component comprising a lens may be designed in a compact configuration. In particular, the lens may be made of a material that is transparent to the electromagnetic radiation generated. The presence of the current spreading layer enables the second semiconductor layer of the n-conductivity type to be contacted with low resistance. Due to the larger dimensions of the chips, which may be contacted well electrically by the described current spreading layer, they may be used in a high power range.

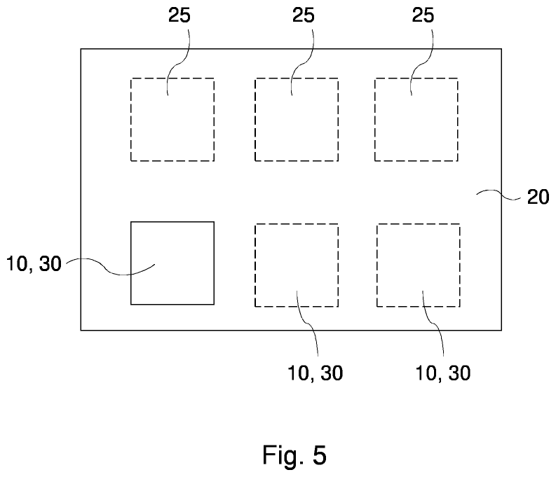

FIG. 5 shows an electronic device 20 according to embodiments. The electronic device 20 may comprise an opto-electronic semiconductor component 10, 30 as described above. As an example, a wavelength of the emitted radiation may be in an infrared range. The wavelength may, for example, be in a range from 750 to 1100 nm.

The electronic device 20 may, for example, be an iris scanner and may include one or more semiconductor laser components 10 or optoelectronic semiconductor components 30 as described above. According to further embodiments, the iris scanner may additionally include one or more detectors 25 by means of which the laser radiation reflected from the iris may be detected. As an example, the iris scanner may work at approximately 810 nm. If the electronic device 20 includes a plurality of semiconductor laser components 10 or a plurality of optoelectronic semiconductor components 30, these may each be designed to be identical or different.

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

1. An optoelectronic semiconductor component comprising:
a first semiconductor layer of a p-conductivity type;
a second semiconductor layer of an n-conductivity type;
an n-doped current spreading layer which contains ZnSe and is directly adjacent to the second semiconductor layer; and
a transparent substrate which is located on a side of the n-doped current spreading layer facing away from the second semiconductor layer.

2. The optoelectronic semiconductor component according to claim 1, further comprising a first and a second resonator mirror.

3. The optoelectronic semiconductor component according to claim 2, in which the first semiconductor layer is part of the first resonator mirror and the second semiconductor layer is part of the second resonator mirror.

4. (canceled)

5. (canceled)

6. The optoelectronic semiconductor component according to claim 1, wherein the transparent substrate is patterned to form a lens.

7. (canceled)

8. The optoelectronic semiconductor component according to claim 1, wherein the optoelectronic semiconductor component is a surface-emitting semiconductor laser component.

9. A method for producing an optoelectronic semiconductor component, comprising:
forming a first semiconductor layer of a p-conductivity type,
thereafter, forming a second semiconductor layer of an n-conductivity type, wherein the first semiconductor layer and the second semiconductor layer are formed over a growth substrate,
forming an n-doped current spreading layer which contains ZnSe and is directly adjacent to the second semiconductor layer, thereby obtaining a workpiece, and
rebonding the workpiece onto a transparent substrate, so that the transparent substrate is arranged on a side of the current spreading layer facing away from the second semiconductor layer.

10. The method according to claim 9, wherein the first semiconductor layer is formed as part of a first resonator mirror and the second semiconductor layer is formed as part of a second resonator mirror.

11. (canceled)

12. (canceled)

13. A method for producing an optoelectronic semiconductor component, comprising:
forming a second semiconductor layer of an n-conductivity type over a growth substrate,
thereafter, forming a first semiconductor layer of a p-conductivity type, thereby obtaining a workpiece,
rebonding the workpiece onto a working substrate, so that the first semiconductor layer is arranged on the side of the working substrate,
thereafter, forming an n-doped current spreading layer which contains ZnSe and is directly adjacent to the second semiconductor layer, and
rebonding the workpiece onto a transparent substrate after forming the current spreading layer so that the transparent substrate is arranged on a side of the current spreading layer facing away from the second semiconductor layer.

14. (canceled)

15. The method of claim 13, further comprising patterning the transparent substrate to form a lens.

16. (canceled)

17. (canceled)

18. (canceled)

19. (canceled)

20. (canceled)
